(19) United States
(12) Patent Application Publication
(10) Pub. No.: US 2024/0047375 A1
(43) Pub. Date: Feb. 8, 2024

(54) CHIP PACKAGE WITH ELECTROMAGNETIC INTERFERENCE SHIELDING LAYER AND METHOD OF MANUFACTURING THE SAME

(71) Applicant: WALTON ADVANCED ENGINEERING, INC., Kaohsiung (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 18/226,782

(22) Filed: Jul. 27, 2023

(30) Foreign Application Priority Data
Aug. 3, 2022 (TW) 111129144

(51) Int. Cl. H01L 23/552; H01L 23/498; H01L 21/48

(52) U.S. Cl. CPC H01L 23/552; H01L 23/49816; H01L 21/4857

(57) ABSTRACT

A chip package with an electromagnetic interference shielding layer and a method of manufacturing the same are provided. The chip package includes a substrate, at least one first circuit layer, at least one second circuit layer, at least one chip, a first insulating layer, and at least one electromagnetic interference shielding layer. The electromagnetic interference shielding layer is made of metals and covering a first surface of the first insulating layer completely for preventing the respective first circuit layers, the respective second circuit layers, and the respective chips from external electromagnetic interference (EMI).

### CROSS-REFERENCE TO RELATED APPLICATIONS

This non-provisional application claims priority under 35 U.S.C. § 119(a) on Patent Application No(s). 111129144 filed in Taiwan, R.O.C. on Aug. 3, 2022, the entire contents of which are hereby incorporated by reference.

### BACKGROUND OF THE INVENTION

The present invention relates to a chip package, especially to a chip package with an electromagnetic interference shielding layer and a method of manufacturing the same,

Semiconductor chips have been applied to different fields including computers, mobile phones, automobiles, medical science, etc. However, while in use, electromagnetic waves in the environment cause electromagnetic interference to the chips and the electromagnetic interference may degrade the performance of the chip or even stop the chip from functioning. Thus there is room for improvement and there is a need to provide a chip package with an electromagnetic interference shielding layer for the semiconductor chips available now.

### SUMMARY OF THE INVENTION

Therefore, it is a primary object of the present invention to provide a chip package with an electromagnetic interference shielding layer and a method of manufacturing the same. The chip package includes a substrate, at least one first circuit layer, at least one second circuit layer, at least one chip, a first insulating layer, and at least one electromagnetic interference shielding layer. The electromagnetic interference shielding layer is made of metals and covering a first surface of the first insulating layer completely for preventing the respective first circuit layers, the respective second circuit layers, and the respective chips from external electromagnetic interference (EMI).

In order to achieve the above object, a chip package with an electromagnetic interference shielding layer according to the present invention includes a substrate, at least one first circuit layer, at least one second circuit layer, at least one chip, a first insulating layer, and at least one electromagnetic interference shielding layer. The substrate consists of a first surface and a second surface opposite to the first surface. At least one blind hole is disposed on the first surface of the substrate while the first circuit layer is arranged at the first surface of the substrate and extending to a surface of an inner wall of the respective blind holes of the substrate. The first circuit layer has a first surface and the second circuit layer is disposed on the second surface of the substrate. The respective first circuit layers are extending to and electrically connected with the respective second circuit layers by the respective blind holes of the substrate. The respective chips are electrically connected with and disposed on the first surface of the respective first circuit layers. The first insulating layer is arranged at the substrate, covering the respective chips, and provided with a first surface. The respective electromagnetic interference shielding layers are made of metals and covering the first surface of the first insulating layer completely for preventing the respective first circuit layers, the respective second circuit layers, and the respective chips from external electromagnetic interference. The respective chips are first electrically connected with the respective first circuit layers which are extending to the respective second circuit layers by the surfaces of the inner walls of the respective blind holes. Thus the respective chips are electrically connected with the outside by the respective second circuit layers. The respective electromagnetic interference shielding layers are arranged at the first surfaces of the first insulating layers correspondingly so that the chip package has a structure provided with the electromagnetic interference shielding layers mounted in an upper layer of the chip package.

A method of manufacturing a chip package according to the present invention includes the following steps. Step S1: providing a substrate which includes a first surface and a second surface opposite to the first surface while at least one blind hole and at least one first circuit layer are arranged at the first surface of the substrate and the first circuit layer is extending to a surface of an inner wall of the respective blind holes of the substrate. The first circuit layer has a first surface and the second surface of the substrate is provided with at least one second circuit layer which includes a first surface. The respective first circuit layers are extending to and electrically connected with the respective second circuit layers by the respective blind holes on the substrate correspondingly. Step S2: arranging at least one chip at the first surface of the respective first circuit layers and the chip is electrically connected with the respective first circuit layers. The chip is first electrically connected with the first surfaces of the respective first circuit layers which are extending to the respective second circuit layers by the surfaces of the inner walls of the respective blind holes correspondingly. Thus the chip is electrically connected with the outside by the first surfaces of the respective second circuit layers. Step S3: disposing a first insulating layer on the substrate while the first insulating layer covering the chip and having a first surface. Step S4: covering the first surface of the first insulating layer completely with at least one electromagnetic interference shielding layer to form the chip package having the electromagnetic interference shielding layer mounted in an upper layer thereof.

Another chip package with an electromagnetic interference shielding layer according to the present invention further includes a second insulating layer besides a substrate, at least one first circuit layer, at least one second circuit layer, at least one chip, a first insulating layer, and at least one electromagnetic interference shielding layer. The electromagnetic interference shielding layer is provided with a first surface. The second insulating layer is arranged at the first surface of the electromagnetic interference shielding layer which is disposed between the first insulating layer and the second insulating layer. Thereby the chip package has a structure with the electromagnetic interference shielding layer disposed in a middle part thereof.

Another method of manufacturing a chip package according to the present invention further includes a step S5 besides the step S1, the step S2, the step S3, and the step S4 mentioned above. The step S5 is disposing a second insulating layer on a first surface of the electromagnetic interference shielding layer to form the chip package with the electromagnetic interference shielding layer located at a middle part thereof.

### BRIEF DESCRIPTION OF THE DRAWINGS

FIG. 1 is a side view of a section of a first embodiment according to the present invention;

FIG. 2 is a side view of a section of a substrate provided with a first circuit layer and a second circuit layer of an embodiment according to the present invention;

FIG. 3 is a side view of a section of the embodiment in FIG. 2 provided with a chip disposed on the first circuit layer according to the present invention;

FIG. 4 is a side view of a section of the embodiment in FIG. 3 provided with a first insulating layer disposed on the substrate according to the present invention;

FIG. 5 is a side view of a section of the embodiment in FIG. 4 provided with an electromagnetic interference shielding layer arranged at the first insulating layer according to the present invention;

FIG. 6 is a side view of a section of a second embodiment according to the present invention;

FIG. 7 is a side view of a section of the embodiment in FIG. 6 provided with a first insulating layer disposed on a substrate according to the present invention;

FIG. 8 is a side view of a section of the embodiment in FIG. 7 provided with an electromagnetic interference shielding layer arranged at the first insulating layer according to the present invention;

FIG. 9 is a side view of a section of the embodiment in FIG. 8 provided with a second insulating layer arranged at the electromagnetic interference shielding layer according to the present invention.

### DETAILED DESCRIPTION OF THE PREFERRED EMBODIMENT

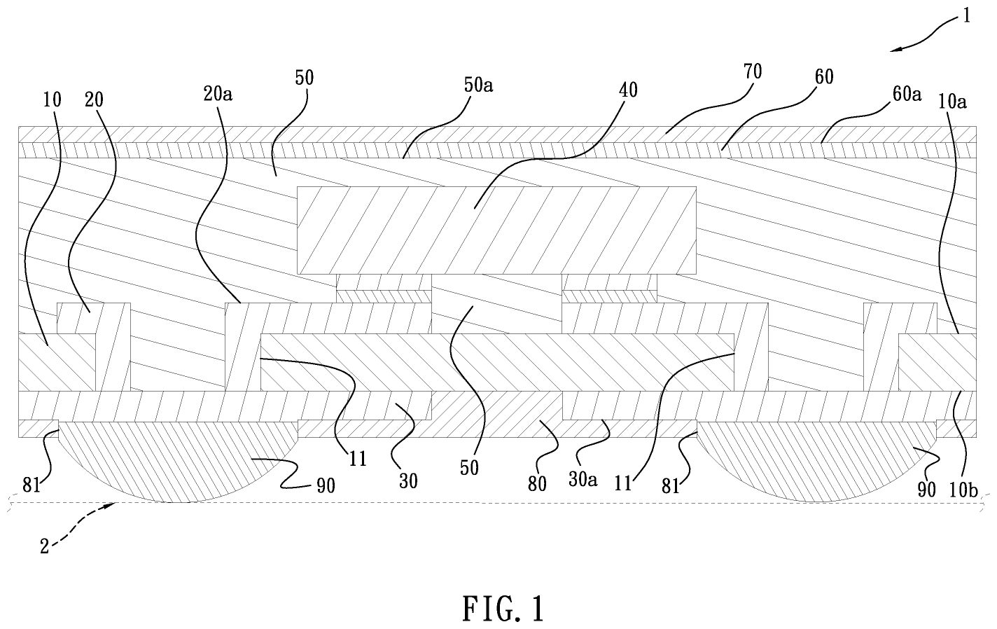

Refer to FIG. 1, a first embodiment of a chip package 1 with an electromagnetic interference shielding layer according to the present invention is provided. The chip package 1 includes a substrate 10, at least one first circuit layer 20, at least one second circuit layer 30, at least one chip 40, a first insulating layer 50, and at least one electromagnetic interference shielding layer 60. The electromagnetic interference shielding layer 60 is made of copper, but not limited.

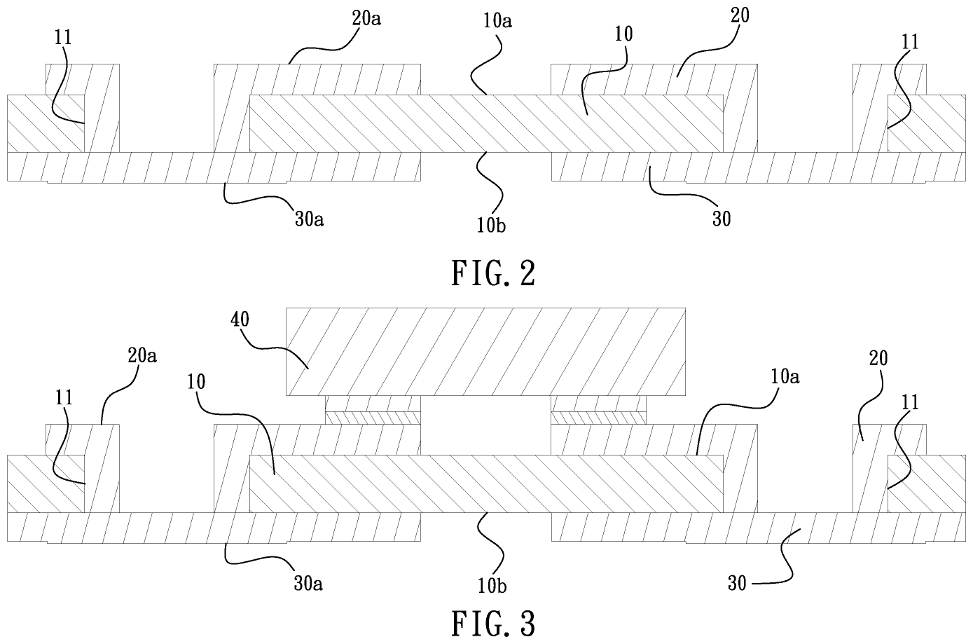

The substrate 10 consists of a first surface 10a and a second surface 10b opposite to the first surface 10a. At least one blind hole 11 is disposed on the first surface 10a of the substrate 10. In this embodiment, there are two blind holes 11, as shown in FIG. 2. But the number of the blind hole 11 is not limited.

The first circuit layer 20 is arranged at the first surface 10a of the substrate 10 and extending to a surface of an inner wall of the respective blind holes 11. The respective first circuit layers 20 have a first surface 20a and there are two first circuit layers 20, as shown in FIG. 2. Yet the number of the first circuit layers 20 is not limited.

The second circuit layer 30 is disposed on the second surface 10b of the substrate 10 and further provided with a first surface 30a. The respective first circuit layers 20 are extending to and electrically connected with the respective second circuit layers 30 by the respective blind holes 11 of the substrate 10, as shown in FIG. 2.

The chip 40 is electrically connected with and disposed on the first surfaces 20a of the respective first circuit layers 20. As shown in FIG. 3, there is one chip 40 but the number of the chip 40 is not limited.

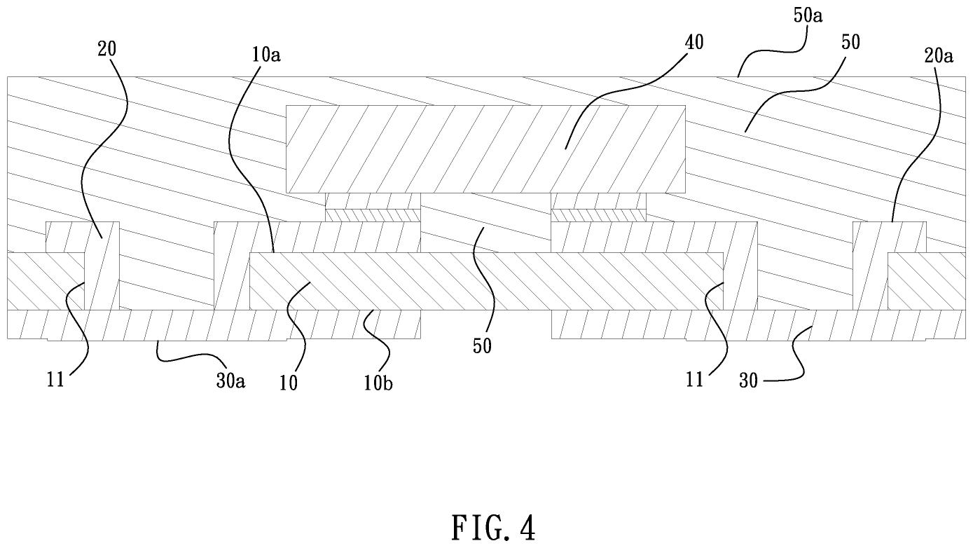

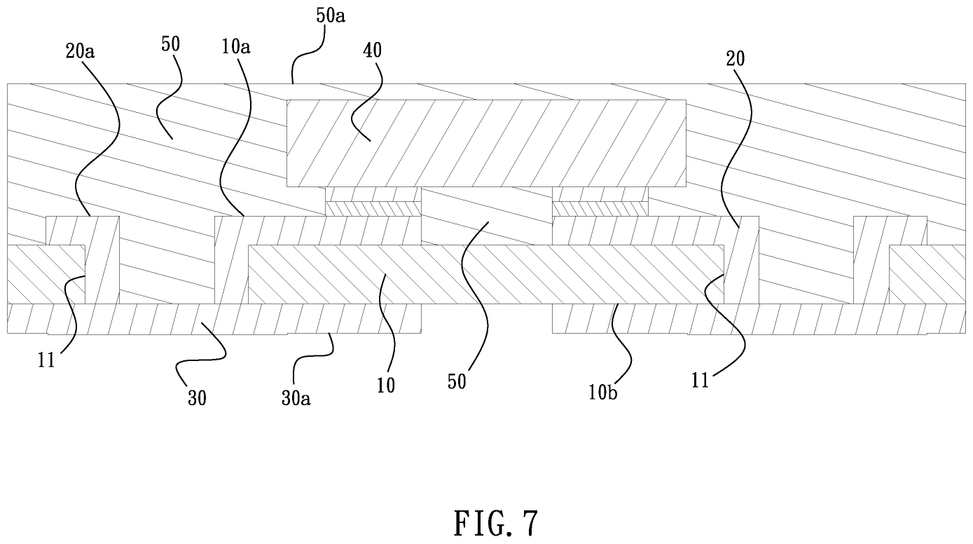

The first insulating layer 50 is mounted to the substrate 10, covering the chip 40, and provided with a first surface 50a, as shown in FIG. 4 and FIG. 7. The chip 40 is electrically connected with the first surfaces 20a of the respective first circuit layers 20 which are extending to the respective second circuit layers 30 by the surfaces of the inner walls of the respective blind holes 11. Thereby the chip 40 is electrically connected with the outside by the respective second circuit layers 30.

The electromagnetic interference shielding layer 60 is made of metal materials and completely covering the first surface 50a of the first insulating layer 50 for preventing the respective first circuit layers 20, the respective second circuit layers 30, and the chip 40 from external electromagnetic interference, as shown in FIG. 1.

Refer to FIG. 1-5, a method of manufacturing the chip package 1 includes the following steps.

Step S1: providing a substrate 10 which includes a first surface 10a provided with at least one blind hole 11 and a second surface 10b opposite to the first surface 10a, as shown I FIG. 2. At least one first circuit layer 20 is arranged at the first surface 10a of the substrate 10 and extending to a surface of an inner wall of the respective blind holes 11 of the substrate 10. The first circuit layer 20 has a first surface 20a, as shown in FIG. 2. The second surface 10b of the substrate 10 is provided with at least one second circuit layer 30 which includes a first surface 30a. The respective first circuit layers 20 are extending to and electrically connected with the respective second circuit layers 30 by the respective blind holes 11 on the substrate 10 correspondingly.

Step S2: arranging at least one chip 40 at the first surface 20a of the respective first circuit layers 20 and the chip 40 is electrically connected with the respective first circuit layers 20, as shown in FIG. 3. The chip 40 is first electrically connected with the first surfaces 20a of the respective first circuit layers 20 which are extending to the respective second circuit layers 30 by the surfaces of the inner walls of the respective blind holes 11 correspondingly. Thus the chip 40 is electrically connected with the outside by the first surfaces 30a of the respective second circuit layers 30.

Step S3: disposing a first insulating layer 50 on the substrate 10, as shown in FIG. 4. The first insulating layer 50 covers the chip 40 and having a first surface 50a.

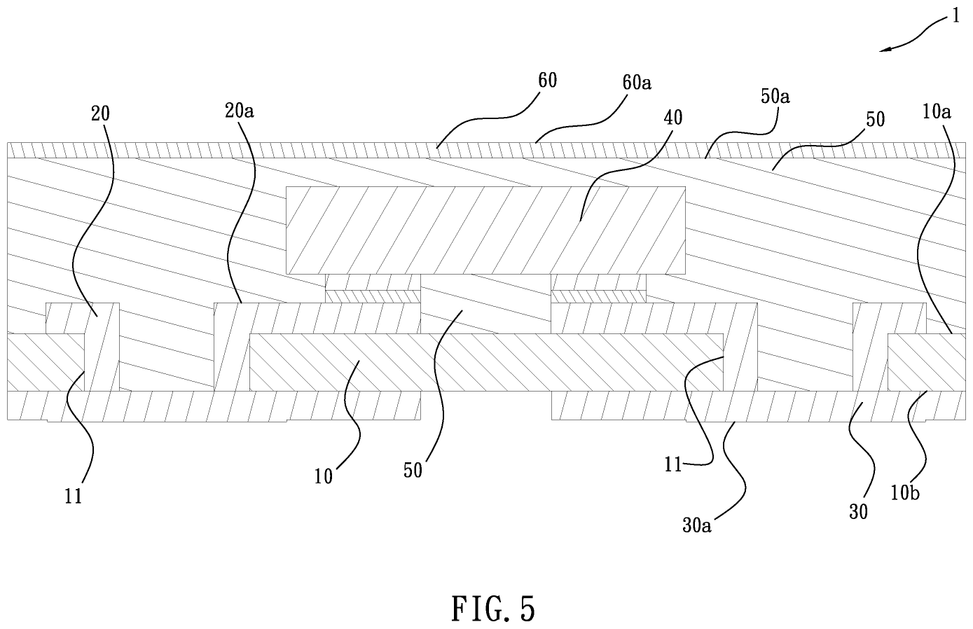

Step S4: covering the first surface 50a of the first insulating layer 50 completely with at least one electromagnetic interference shielding layer 60, as shown in FIG. 5. The electromagnetic interference shielding layer 60 is used to prevent the respective first circuit layers 20, the respective second circuit layers 30, and the chip 40 from external electromagnetic interference. Thereby production of the chip package 1 is completed.

Refer FIG. 1, the chip package 1 is further provided with at least one first outer protective layer 70 and at least one second outer protective layer 80 for protection of the chip package 1.

The first outer protective layer 70 is disposed on the first surface 60a of the electromagnetic interference shielding layer 60 while the second outer protective layer 80 is arranged at the first surface 30a of the second circuit layer 30 and provided with at least one opening 81 for allowing the first surface 30a of the respective second circuit layers 30 to be exposed.

Refer to FIG. 1, each of the openings 81 of the second outer protective layer 80 is provided with a solder ball 90 which is electrically connected with the first surface 30a of the second circuit layer 30 so that the chip 40 can be electrically connected with the outside such as a circuit board 2 (printed circuit board (PCB)) by the respective solder balls 90 but not limited to the circuit board 2.

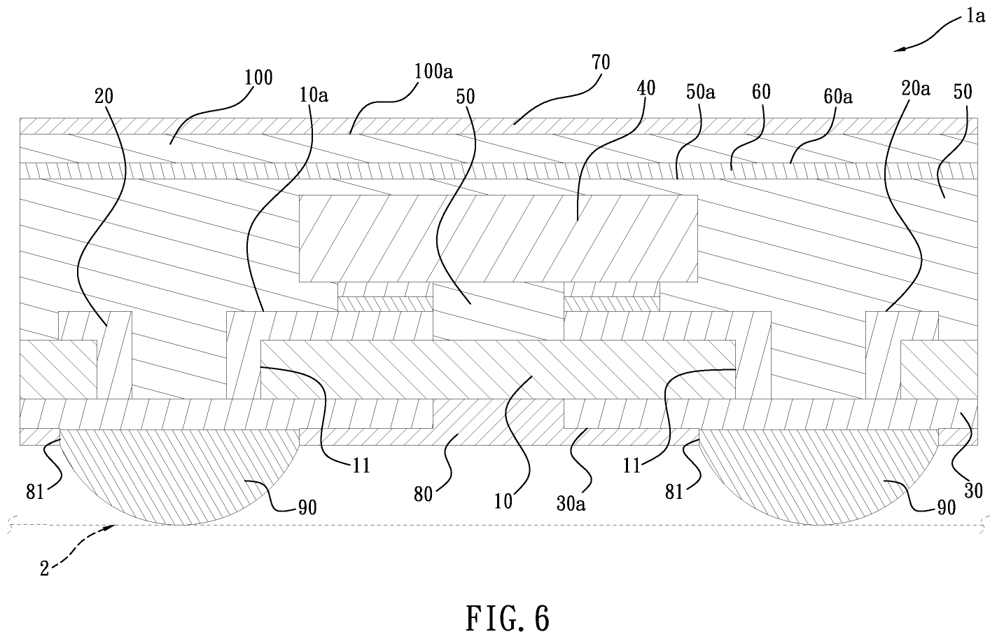

Refer to FIG. 6, a second embodiment of a chip package la with an electromagnetic interference shielding layer according to the present invention is provided. The chip package la includes a substrate 10, at least one first circuit layer 20, at least one second circuit layer 30, at least one chip 40, a first insulating layer 50, and at least one electromagnetic interference shielding layer 60. A structure or technical feature of the second embodiment is about the same as that of the first embodiment.

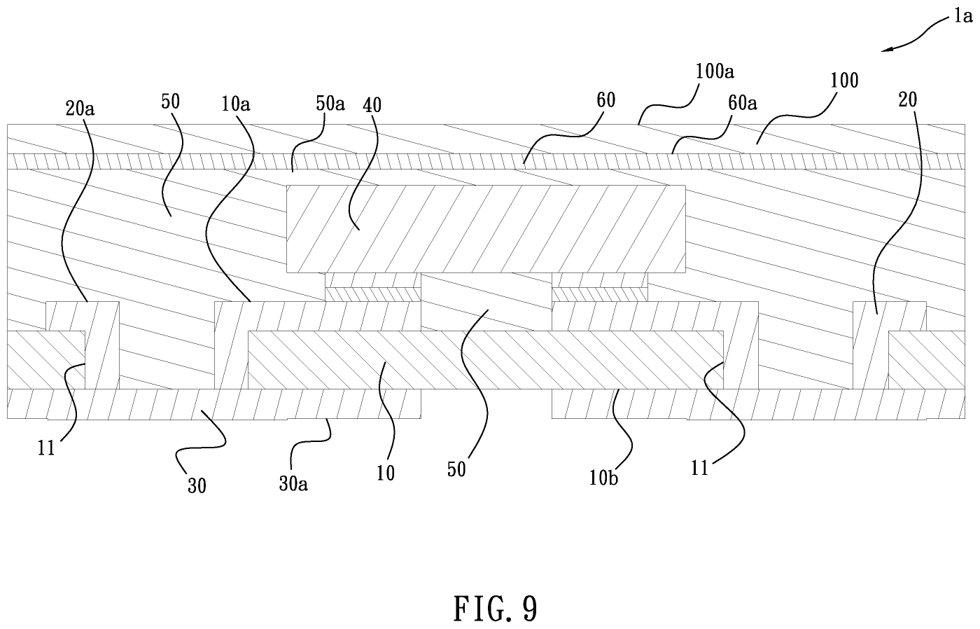

The first embodiment (as shown in FIG. 1 or FIG. 5) and the second embodiment (as shown in FIG. 6 or FIG. 9) are mainly different in that the electromagnetic interference shielding layer 60 of the chip package 1 of the first embodiment is disposed on the first surface 50a of the first insulating layer 50 so that the chip package 1 of the first embodiment has a structure provided with the electromagnetic interference shielding layer 60 mounted in the upper layer thereof, as shown in FIG. 1 and FIG. 5. Yet the chip package 1a of the second embodiment further includes a second insulating layer 100 which is arranged at a first surface 60a of the electromagnetic interference shielding layer 60, as shown in FIG. 9, and the position of the electromagnetic interference shielding layer 60 has changed to be disposed between the first insulating layer 50 and the second insulating layer 100. Thereby the chip package la of the second embodiment has a structure with the electromagnetic interference shielding layer 60 disposed in a middle part thereof.

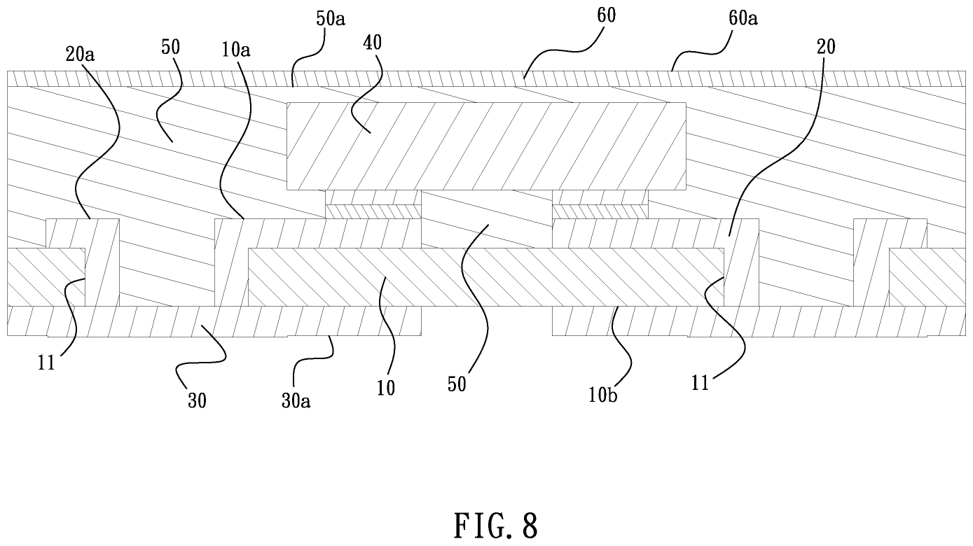

Refer to FIG. 2, FIG. 3, and FIG. 6-9, a method of manufacturing the chip package 1a of the second embodiment further includes a step S5 besides the steps S1 to S4 of the first embodiment. The step S5 is disposing a second insulating layer 100 on a first surface 60a of the electromagnetic interference shielding layer 60 to form the chip package 1a with the electromagnetic interference shielding layer 60 located at a middle part thereof.

Refer to FIG. 6, the chip package la of the second embodiment further includes at least one first outer protective layer 70 and at least one second outer protective layer 80. The first outer protective layer 70 is mounted to a first surface 100a of the second insulating layer 100. As to other structural design or arrangement of the second outer protective layer 80 including the opening 81 or the solder ball 90 of the second embodiment, it is the same as that of the chip package 1 of the first embodiment (as shown in FIG. 1).

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A chip package having electromagnetic interference shielding layer comprising:
a substrate which includes a first surface provided with at least one blind hole and a second surface opposite to the first surface;
at least one first circuit layer which is arranged at the first surface of the substrate, extending to a surface of an inner wall of the blind hole of the substrate, and having a first surface;
at least one second circuit layer which is disposed on the second surface of the substrate; wherein the first circuit layer is extending to and electrically connected with the second circuit layer by the blind hole of the substrate;
at least one chip electrically connected with and disposed on the first surface of the first circuit layer;
a first insulating layer which is arranged at the substrate, covering the chip, and provided with a first surface; and
at least one electromagnetic interference shielding layer made of metal and covering the first surface of the first insulating layer completely for preventing the first circuit layer, the second circuit layer, and the chip from electromagnetic interference;
wherein the chip is first electrically connected with the first surface of the first circuit layer which is extending to the second circuit layer by the surface of the inner wall of the blind hole so that the chip is electrically connected with the outside by the second circuit layer.

2. The chip package as claimed in claim 1, wherein the electromagnetic interference shielding layer is made of copper.

3. The chip package as claimed in claim 1, wherein the second circuit layer further includes a first surface; wherein the electromagnetic interference shielding layer is provided with a first surface; wherein the chip package further includes at least one first outer protective layer and at least one second outer protective layer; wherein the first outer protective layer is disposed on the first surface of the electromagnetic interference shielding layer; wherein the second outer protective layer is arranged at the first surface of the second circuit layer and provided with at least one opening for allowing the first surface of the second circuit layer to be exposed.

4. The chip package as claimed in claim 3, wherein the opening of the second outer protective layer is provided with a solder ball which is electrically connected with the first surface of the second circuit layer so that the chip is able to be electrically connected with the outside by the solder ball.

5. A method of manufacturing a chip package comprising the steps of:
Step S1: providing a substrate which includes a first surface and a second surface opposite to the first surface while at least one blind hole and at least one first circuit layer are arranged at the first surface of the substrate and the first circuit layer is extending to a surface of an inner wall of the blind hole of the substrate; wherein the first circuit layer has a first surface and the second surface of the substrate is provided with at least one second circuit layer which includes a first surface; wherein the first circuit layer is extending to and electrically connected with the second circuit layer by the blind hole on the substrate;
Step S2: arranging at least one chip at the first surface of the first circuit layer and the chip is electrically connected with the first circuit layers; the chip is first electrically connected with the first surface of the first circuit layer and then electrically connected with the outside by the first surface of the second circuit layer because that the first circuit layer is extending to the second circuit layer by the surface of the inner wall of the blind hole;
Step S3: disposing a first insulating layer on the substrate while the first insulating layer covering the chip and having a first surface; and
Step S4: covering the first surface of the first insulating layer completely with at least one electromagnetic interference shielding layer for preventing the first circuit layer, the second circuit layer, and the chip from electromagnetic interference;
thereby manufacturing of the chip package is completed.

6. A chip package having electromagnetic interference shielding layer comprising:
a substrate which includes a first surface provided with at least one blind hole and a second surface opposite to the first surface;
at least one first circuit layer which is arranged at the first surface of the substrate, extending to a surface of an inner wall of the blind hole of the substrate, and having a first surface;
at least one second circuit layer which is disposed on the second surface of the substrate; wherein the first circuit layer is extending to and electrically connected with the second circuit layer by the blind hole of the substrate;
at least one chip electrically connected with and disposed on the first surface of the first circuit layer;
a first insulating layer which is arranged at the substrate, covering the chip, and provided with a first surface;
at least one electromagnetic interference shielding layer which is made of metal and covering the first surface of the first insulating layer completely for preventing the first circuit layer, the second circuit layer, and the chip from electromagnetic interference;
wherein the electromagnetic interference shielding layer is provided with a first surface, and
a second insulating layer disposed on the first surface of the electromagnetic interference shielding layer;
wherein the chip is first electrically connected with the first surface of the first circuit layer which is extending to the second circuit layer by the surface of the inner wall of the blind hole so that the chip is electrically connected with the outside by the second circuit layer.

7. The chip package as claimed in claim 6, wherein the electromagnetic interference shielding layer is made of copper.

8. The chip package as claimed in claim 6, wherein the second circuit layer further includes a first surface; wherein the second insulating layer is provided with a first surface; wherein the chip package further includes at least one first outer protective layer and at least one second outer protective; wherein the first outer protective layer is disposed on the first surface of the second insulating layer; wherein the second outer protective layer is arranged at the first surface of the second circuit layer and provided with at least one opening for allowing the first surface of the second circuit layer to be exposed.

9. The chip package as claimed in claim 8, wherein the opening of the second outer protective layer is provided with a solder ball which is electrically connected with the first surface of the second circuit layer so that the chip is electrically connected with the outside by the solder ball.

10. A method of manufacturing a chip package comprising the steps of:
Step S1: providing a substrate which includes a first surface and a second surface opposite to the first surface while at least one blind hole and at least one first circuit layer are arranged at the first surface of the substrate and the first circuit layer is extending to a surface of an inner wall of the blind hole of the substrate; wherein the first circuit layer has a first surface and the second surface of the substrate is provided with at least one second circuit layer which includes a first surface; wherein the first circuit layer is extending to and electrically connected with the second circuit layer by the blind hole on the substrate;
Step S2: arranging at least one chip at the first surface of the first circuit layer and the chip is electrically connected with the first circuit layers; the chip is first electrically connected with the first surface of the first circuit layer and then electrically connected with the outside by the first surface of the second circuit layer because that the first circuit layer is extending to the second circuit layer by the surface of the inner wall of the blind hole;
Step S3: disposing a first insulating layer on the substrate while the first insulating layer covering the chip and having a first surface;
Step S4: covering the first surface of the first insulating layer completely with at least one electromagnetic interference shielding layer for preventing the first circuit layer, the second circuit layer, and the chip from electromagnetic interference;
wherein the electromagnetic interference shielding layer having a first surface; and
Step S5: disposing a second insulating layer on the first surface of the electromagnetic interference shielding layer to form the chip package with the electromagnetic interference shielding layer.
